(19) United States
(12) Patent Application Publication
(10) Pub. No.: US 2025/0316524 A1
(43) Pub. Date: Oct. 9, 2025

(54) WAFER CLEANING DEVICE INCLUDING CHUCK TABLE

(71) Applicant: Samsung Electronics Co., Ltd., Suwon-si (KR)

(72) Inventors: Inhak JEON, Suwon-si (KR); Donghoon KWON, Suwon-si (KR); Youngin KIM, Suwon-si (KR); Jihoon PARK, Suwon-si (KR); Seungyong YU, Suwon-si (KR); Byungsoo JOO, Suwon-si (KR)

(73) Assignee: Samsung Electronics Co., Ltd., Suwon-si (KR)

(21) Appl. No.: 18/999,955

(22) Filed: Dec. 23, 2024

(30) Foreign Application Priority Data
Apr. 8, 2024 (KR) 10-2024-0047267

(51) Int. Cl. H01L 21/687; H01L 21/67; H01L 21/683

(52) U.S. Cl. CPC H01L 21/68742; H01L 21/67051; H01L 21/6838

(57) ABSTRACT

A chuck table includes: a chuck stage configured to have a wafer seated thereon; a plurality of first ports on the chuck stage and configured to adsorb the wafer to the chuck stage; a plurality of second ports on the chuck stage and configured to have a liquid from the chuck stage sucked therethrough; and a pressure adjuster connected to the plurality of first ports and configured to provide a vacuum pressure, wherein each of the plurality of first ports is configured to be selectively opened and closed to communicate with an exterior of the chuck stage, and the plurality of second ports are open to communicate with the exterior of the chuck stage.

### CROSS-REFERENCE TO RELATED APPLICATION

This application claims priority to Korean Patent Application No. 10-2024-0047267, filed on Apr. 8, 2024, in the Korean Intellectual Property Office, the entire disclosure of which is incorporated by reference herein for all purposes.

### BACKGROUND

### 1. Field

The present disclosure relates to a wafer cleaning device including a chuck table.

### 2. Description of the Related Art

The manufacturing process of semiconductor elements requires a chemical mechanical polishing (CMP) process to planarize the surface of a wafer. The CMP process is performed by repeatedly performing unit processes such as polishing, buffing, and cleaning on the wafer surface. Among the unit processes, the cleaning process is performed after unit processes such as polishing to remove residual debris or foreign substances from the wafer surface and is treated as important to prevent damage to the wafer caused by these foreign substances. However, wafer cleaning processes require apparatuses that are costly and require high maintenance. The above description is information the inventor(s) acquired during the course of conceiving the present disclosure, or already possessed at the time, and is not necessarily art publicly known before the present application was filed.

### SUMMARY

The present disclosure provides a chuck table capable of securely gripping a wafer during surface treatment processes, such as a cleaning process, and a wafer cleaning device including the chuck table.

According to an aspect of the disclosure, a chuck table includes: a chuck stage configured to have a wafer seated thereon; a plurality of first ports on the chuck stage and configured to adsorb the wafer to the chuck stage; a plurality of second ports on the chuck stage and configured to have a liquid from the chuck stage sucked therethrough; and a pressure adjuster connected to the plurality of first ports and configured to provide a vacuum pressure, wherein each of the plurality of first ports is configured to be selectively opened and closed to communicate with an exterior of the chuck stage, and the plurality of second ports are open to communicate with the exterior of the chuck stage.

According to an aspect of the disclosure, a wafer cleaning device includes: a chuck table configured to support a wafer; a fluid supplier configured to supply a cleaning liquid to the wafer on the chuck table; and a cleaning module configured to clean the wafer on the chuck table, wherein the chuck table includes: a chuck stage; a backing plate on the chuck stage, the backing plate including a support surface configured to have the wafer seated thereon, the backing plate including a plurality of first through holes and a plurality of second through holes passing through the support surface; a plurality of first ports on the chuck stage and configured to communicate with the plurality of first through holes and to adsorb the wafer to the support surface; a plurality of second ports on the chuck stage and configured to communicate with the plurality of second through holes and configured to have the cleaning liquid from the support surface sucked therethrough; and a pressure adjuster connected to the plurality of first ports and configured to provide a vacuum pressure, wherein each of the plurality of first ports is configured to be selectively opened and closed to communicate with the plurality of first through holes, and the plurality of second ports are open to communicate with the plurality of second through holes.

According to an aspect of the disclosure, a wafer cleaning method includes: transferring a wafer to a position adjacent to a chuck table; sucking a cleaning liquid remaining on a support surface of the chuck table through a suction port on the chuck table; loading the wafer onto the support surface of the chuck table; opening a vacuum port on the chuck table; adsorbing the wafer loaded onto the chuck table by providing negative pressure to the vacuum port; and cleaning the wafer adsorbed to the chuck table.

Additional aspects of embodiments will be set forth in part in the description which follows and, in part, will be apparent from the description, or may be learned by practice of the disclosure.

A chuck table according to the disclosure is provided with a vacuum port for adsorbing a wafer and a suction port for adjusting the thickness of a water film separately, thereby reducing or preventing the decrease in suction power of the vacuum port caused by the water film remaining on the surface of the chuck table.

The chuck table according to the disclosure may stably and efficiently grip the wafer during wafer loading and gripping processes by providing a vacuum port that may be selectively opened and closed by a shutter.

### BRIEF DESCRIPTION OF THE DRAWINGS

The above and/or other aspects, features, and advantages of the present disclosure will become apparent and more readily appreciated from the following description of embodiments, taken in conjunction with the accompanying drawings, in which:

FIG. 1 illustrates an example of a wafer cleaning device according to one or more embodiments;

FIG. 2A is a perspective view of a chuck table according to one or more embodiments;

FIG. 2B is a plan view of a chuck table illustrating a state in which a first port is open according to one or more embodiments;

FIG. 2C is a plan view of a chuck table illustrating a state in which the first port is closed according to one or more embodiments;

FIG. 3A is a plan view of a chuck table and illustrates a state in which a shutter is positioned to open a first port according to one or more embodiments;

FIG. 3B is a partial cross-sectional view of the chuck table taken along line A-A of FIG. 3A and illustrates a state in which a shutter opens the first port according to one or more embodiments;

FIG. 3C is a plan view of the chuck table and illustrates a state in which the shutter is positioned to close the first port according to one or more embodiments;

FIG. 3D is a partial cross-sectional view of the chuck table taken along line B-B of FIG. 3B and illustrates a state in which the shutter closes the first port according to one or more embodiments;

FIG. 3E is a plan view of the chuck table according to one or more embodiments;

FIG. 4 is a partial cross-sectional view of a chuck table according to one or more

embodiments;

FIG. 5A is a partial cross-sectional view of a chuck table according to one or more embodiments;

FIG. 5B is a partial cross-sectional view of the chuck table according to one or more embodiments;

FIG. 6A is a plan view of a chuck table and illustrates a state in which a first port is open according to one or more embodiments;

FIG. 6B is a plan view of the chuck table and illustrates a state in which the first port is closed according to one or more embodiments;

FIG. 7A is a plan view of a chuck table and illustrates a state in which a first port is open according to one or more embodiments;

FIG. 7B is a plan view of the chuck table and illustrates a state in which the first port is closed according to one or more embodiments;

FIG. 8 is a plan view of a chuck table according to one or more embodiments;

FIG. 9A is a partial cross-sectional view of a chuck table and illustrates a state in which a first port is open according to one or more embodiments;

FIG. 9B is a partial cross-sectional view of the chuck table and illustrates a state in which the first port is closed according to one or more embodiments; and

FIG. 10 is a flowchart of a wafer cleaning method according to one or more embodiments.

### DETAILED DESCRIPTION

Hereinafter, embodiments will be described in detail with reference to the accompanying drawings. When describing the embodiments with reference to the accompanying drawings, like reference numerals refer to like elements and a repeated description related thereto will be omitted.

It should be appreciated that embodiments of the disclosure and the terms used therein are not intended to limit the technological features set forth herein to particular embodiments and include various changes, equivalents, or replacements for a corresponding embodiment. In connection with the description of the drawings, like reference numerals may be used for similar or related components.

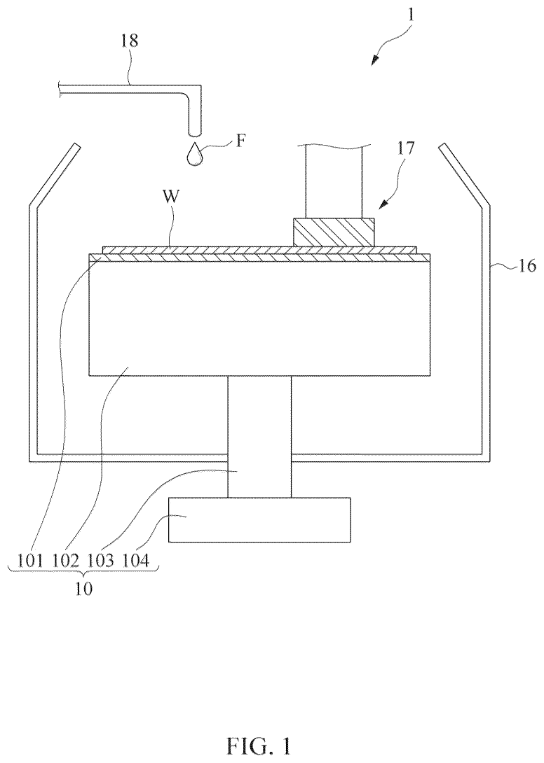

FIG. 1 schematically illustrates a wafer cleaning device according to one or more embodiments.

Referring to FIG. 1, a wafer cleaning device 1 may be used to clean a surface of a wafer W. For example, the wafer cleaning device 1 may be used during a chemical mechanical polishing (CMP) process to polish the surface of the wafer W. The wafer cleaning device 1 may be used to remove debris or foreign substances remaining on the surface (e.g., a polishing surface) of the wafer W after polishing the wafer W. The wafer cleaning device 1 may be used to sequentially clean a plurality of wafers W. As understood by one of ordinary skill in the art, a CMP process is a fabrication process that uses a combination of chemical and mechanical forces to smooth surfaces. CMP may be used for removing surface irregularities from silicon wafers. In one or more examples, CMP uses a slurry of nano-sized abrasive particles in a chemically reactive solution to remove material. The chemical reaction softens the material, while the mechanical abrasion removes the softened material.

In one or more embodiments, the wafer cleaning device 1 may include a chuck table 10 on which the wafer W is seated, a fluid supplier 18 for supplying a fluid F, a cleaning module 17 for cleaning the wafer W, and a bowl 16 disposed to surround the periphery of the chuck table 10.

The chuck table 10 may support the wafer W seated on the upper portion of the chuck table 10. The chuck table 10 may maintain the position of the wafer W so that the wafer W does not deviate from the set seating position (e.g., wafer does not substantially move) while a cleaning process is performed on the wafer W. The chuck table 10 may be used during various semiconductor manufacturing processes (e.g., a wet etching process and a polishing process) that are performed while a fluid is applied to the surface of the wafer W. In one or more embodiments, the chuck table 10 may include a chuck stage 102, a backing plate 101 disposed on the upper portion of the chuck stage 102, a spindle 103 for rotating the chuck stage 102, and a driver 104.

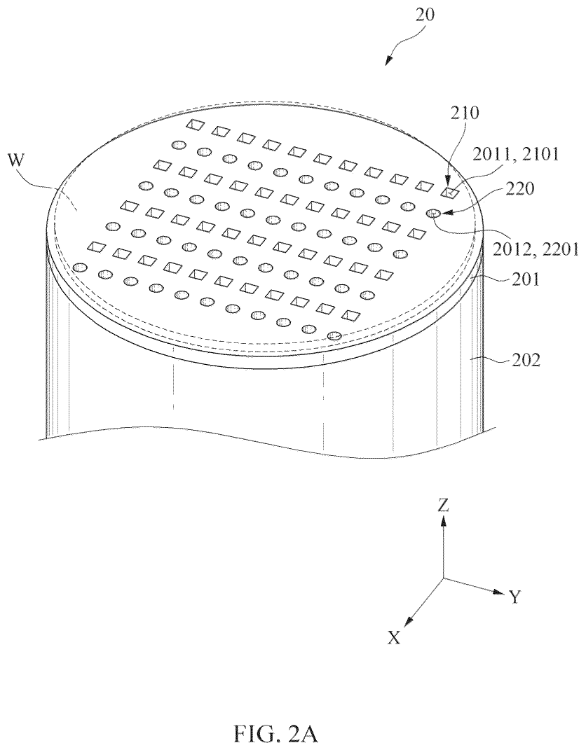

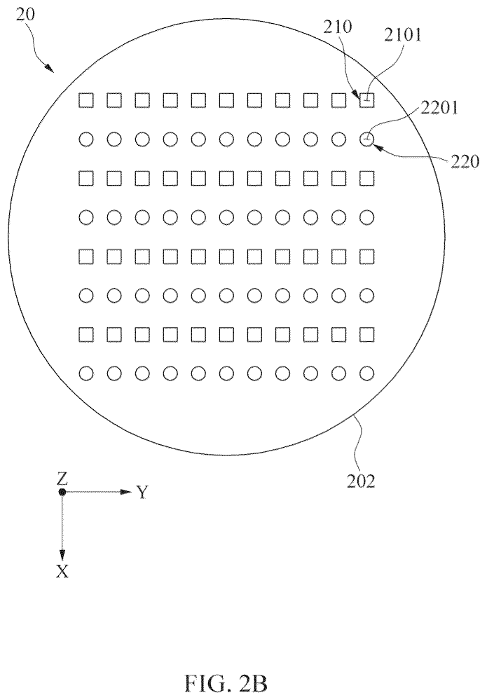

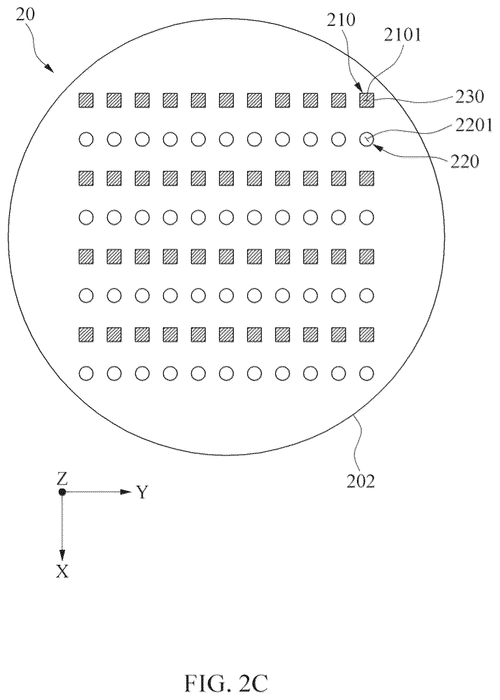

The chuck stage 102 may rotate about a central axis perpendicular to the ground while supporting the wafer W. For example, the chuck stage 102 may be rotated by the spindle 103. A plurality of ports may be formed in the chuck stage 102. For example, the chuck stage 102 may include a first port (or a vacuum port) (e.g., a first port 210 of FIG. 2A) for adsorbing the seated wafer W and a second port (or a suction port) (e.g., a second port 220 of FIG. 2A) for sucking a fluid on the upper surface to control the amount of fluid.

The backing plate 101 may be disposed on the upper portion of the chuck stage 102 and may support the wafer W by directly contacting the surface of the wafer W. The backing plate 101 may form a support surface on which the wafer W is seated. The backing plate 101 may be formed of a flexible material, for example, a material of which a shape is partially deformable, such as urethane. However, as will be understood by one of ordinary skill in the art, any suitable flexible material may be used for the backing plate 101. The backing plate 101, which is seated in close contact with the surface of the wafer W, may support the wafer W such that the wafer W is not separated or substantially moved from the chuck table 10 while the cleaning process is performed. The backing plate 101 may be detachably connected to the upper portion of the chuck stage 102 and may be replaced as needed during use.

The spindle 103 may be connected to the chuck stage 102 and rotate the chuck stage 102 by receiving power from the driver 104. The rotation direction and rotation velocity of the spindle 103 may be adjusted according to a set input value.

In one or more embodiments, the fluid supplier 18 may supply the fluid F toward the surface of the chuck table 10, for example, the backing plate 101. The fluid F supplied by the fluid supplier 18 may be a cleaning liquid, such as deionized water (DIW), for wafer cleaning. However, any suitable cleaning liquid known to one of ordinary skill in the art may be used.

In one or more embodiments, the cleaning module 17 may clean the surface of the wafer W seated on the chuck table 10. The height and position of the cleaning module 17 may be adjusted with respect to the chuck table 10. The cleaning module 17 may be in contact with the surface of the wafer W and configured to remove foreign substances or debris from the surface of the wafer W.

FIG. 2A is a perspective view of a chuck table. FIG. 2B is a plan view of the chuck table and illustrates a state in which a first port is open. FIG. 2C is a plan view of the chuck table and illustrates a state in which the first port is closed.

Referring to FIG. 2A, the chuck table 20 may include a chuck stage 202, a backing plate 201 disposed on the upper portion of the chuck stage 202, the first port 210, and the second port 220.

A plurality of first ports (e.g., 210) and a plurality of second ports (e.g., 220) may be formed on the chuck stage 202. The first port 210 and the second port 220 may be disposed not to overlap each other in a state in which the chuck table 20 is viewed from above. The first port 210 and the second port 220 may be formed in various numbers and arrangements on the chuck table 20. For example, as illustrated in FIGS. 2A-2C, the first and second ports are disposed in alternating rows and/or columns forming a 2-D grid. However, as understood by one of ordinary skill in the art, the embodiments are not limited to this configuration, the first and second ports may be disposed in any number of suitable arrangements.

The backing plate 201 may be disposed on the upper portion of the chuck stage 202 and may directly support the wafer W. The backing plate 201 may be formed with a plurality of through holes (e.g., a first through hole 2011 and a second through hole 2012) that communicate with the first port 210 and the second port 220 formed on the chuck stage 202, respectively. For example, the backing plate 201 may include a plurality of first through holes (e.g., 2011) and a plurality of second through holes (e.g., 2012) formed through positions corresponding to the plurality of first ports (e.g., 210) and the plurality of second ports (e.g., 220). For example the first ports 210 and the second ports 220 define the first through holes 2011 and the second through holes 2012, respectively.

In one or more embodiments, the first port 210 (or a vacuum port) may adsorb the wafer W to the chuck table 20. For example, the first port 210 may include a first flow path 2101 communicating with the first through hole 2011 and adsorb the wafer W to the backing plate 201 by applying negative pressure to the first flow path 2101. In one or more embodiments, the second port 220 (or a suction port) may adjust the thickness of a water film remaining on the upper portion of the chuck table 20. For example, the second port 220 may include a second flow path 2201 communicating with the second through hole 2021 configured to adjust the thickness of a liquid remaining on the surface of the backing plate 201, where the liquid (e.g., DIW) remaining on the surface of the backing plate 201 is sucked or evacuated through the second flow path 2201.

Referring to FIGS. 2B and 2C, the first port 210 may be selectively opened (e.g., open state) and closed (e.g., closed state) during each stage of the wafer cleaning process. For example, the first port 210 may be selectively opened and closed depending on whether the wafer is seated on the chuck table 20. According to this structure, it is possible to advantageously minimize or prevent the liquid (e.g., DIW) remaining on the backing plate 201 from flowing into the first flow path 2101 during the wafer replacement process. Accordingly, by opening and closing the first port 210, it is possible to advantageously minimize or prevent the weakening of the negative pressure acting on the first flow path 2101 caused by the fluid flowing into the first flow path 2101.

In one or more embodiments, the first flow path 2101 of each first port 210 may be formed to pass through the interior of the chuck stage 202. The air flow through the first flow path 2101 may be selectively blocked according to the opening and closing operation of the first port 210. For example, each first port 210 may be installed or formed in the first flow path 2101 and, may include a shutter 230 that operates to open and close the first flow path 2101. In one or more embodiments, the opening and closing operations of the plurality of first ports (e.g., 210) may be performed simultaneously. For example, the chuck table 20 may be configured such that the plurality of first ports (e.g., 210) is simultaneously opened, as illustrated in FIG. 2B, and that the plurality of first ports (e.g., 210) is simultaneously closed, as illustrated in FIG. 2C. However, as understood by one of ordinary skill in the art, the embodiments of the present disclosure are not limited to this configuration. For example, only a portion or subset of the plurality of first ports may be simultaneously opened or closed.

In one or more embodiments, the plurality of first ports (e.g., 210) may be connected to each other inside the chuck stage 202, and pressure may be adjusted simultaneously by a pressure adjuster. For example, the pressure applied by the pressure adjuster may be equally applied to the plurality of first ports (e.g., 210) at the same time. The plurality of first ports (e.g., 210) may be configured to be open when the wafer W is seated on the chuck stage 202, and the pressure adjuster may be configured to provide vacuum pressure to the first port 210 while the first port 210 is open.

The second flow path 2201 of each second port 220 may be formed through the interior of the chuck stage 202. The liquid remaining on the upper portion of the chuck table 20 may flow into the second flow path 2201. The second port 220 may remain open so that the second flow path 2201 communicates with the exterior of the chuck stage 202, that is, with the second through hole. For example, the second port 220 may always remain open so that a liquid (e.g., DIW) remaining on a support surface may be sucked into the chuck stage 202. The second port 220 may maintain the thickness of the water film formed by the liquid remaining on the support surface within a set range, where the liquid remaining on the support surface is sucked or evacuated through the second port. In one or more examples, a suction force may be applied to the second port 220 that causes the liquid to be sucked through the second port 220. For example, a compressor may be used that causes liquid remaining on the support surface to be sucked or evacuated through the second port. According to this structure, the thickness of the liquid remaining on the upper portion of the chuck table 20 may be adjusted through the second port 220 to minimize or prevent the phenomenon of the water film remaining on the support surface excessively thickening, thereby advantageously minimizing or preventing the seated wafer from separating from the chuck table 20 during the cleaning process.

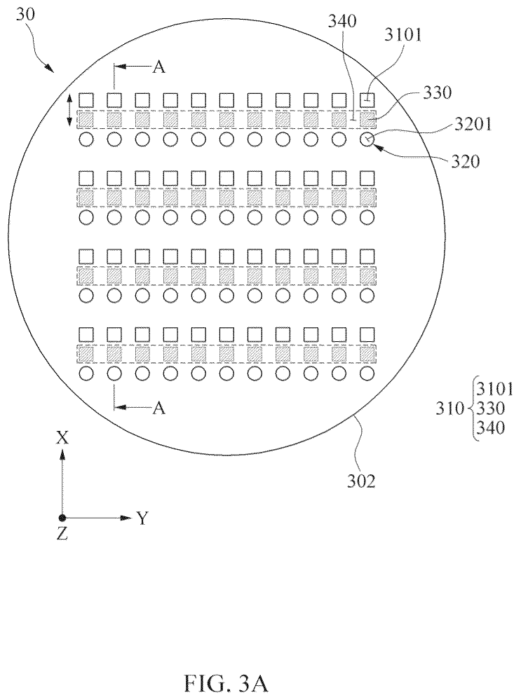

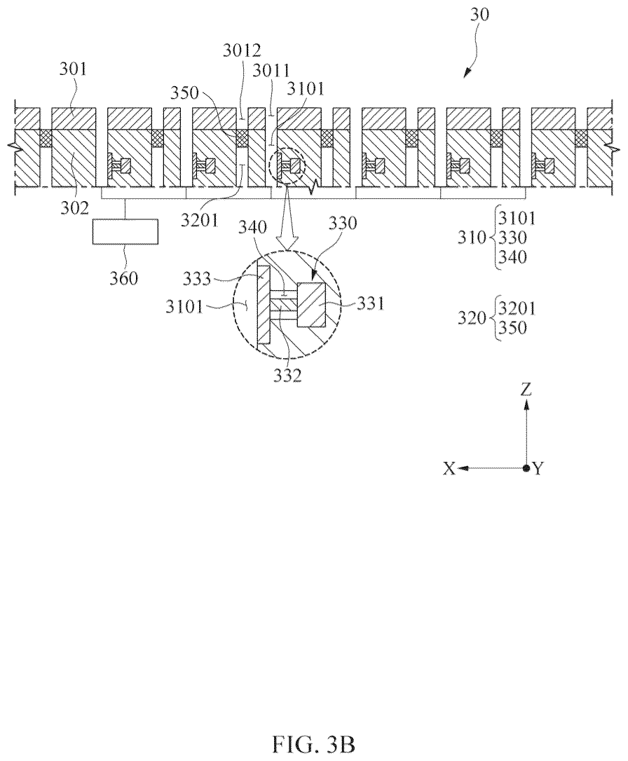

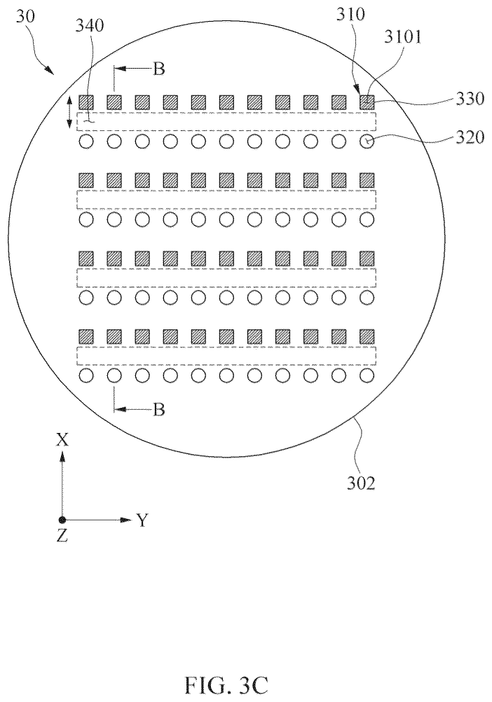

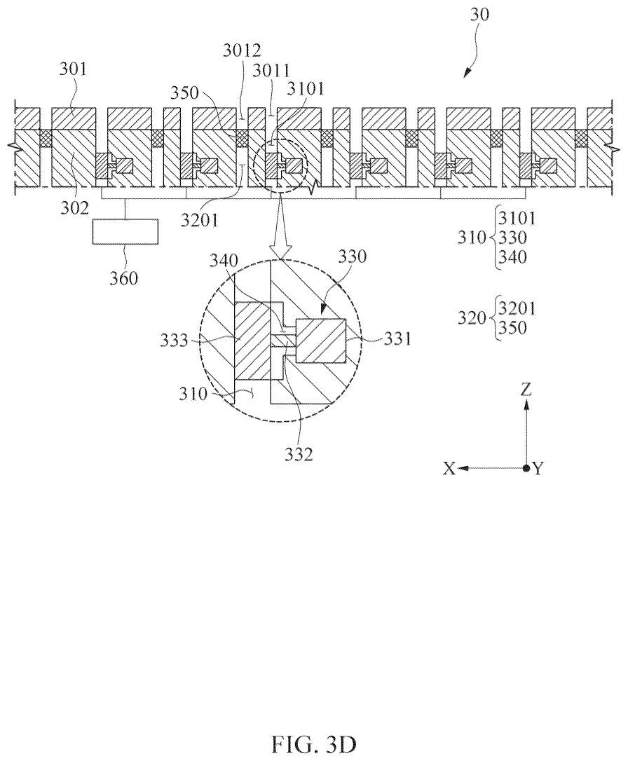

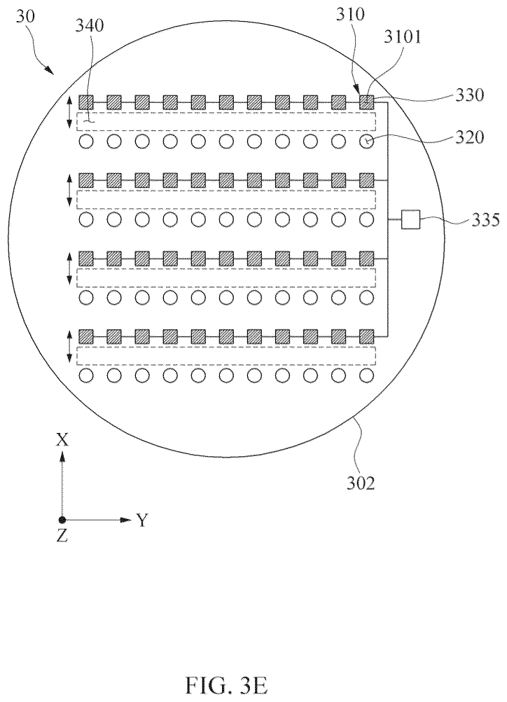

FIG. 3A is a plan view of a chuck table and illustrates a state in which a shutter is positioned to open a first port. FIG. 3B is a partial cross-sectional view of the chuck table taken along line A-A of FIG. 3A. FIG. 3C is a plan view of the chuck table and illustrates a state in which the shutter is positioned to close the first port. FIG. 3D is a partial cross-sectional view of the chuck table taken along line B-B of FIG. 3C. FIG. 3E is a plan view of the chuck table. For reference, FIGS. 3A and 3B illustrate a state in which the shutter opens the first port and FIGS. 3C and 3D illustrate a state in which the shutter closes the first port.

Referring to FIGS. 3A to 3D, a chuck table 30 may include a chuck stage 302, a backing plate 301, a plurality of first ports 310 formed on the chuck stage 302, and a plurality of second ports 320 formed on the chuck stage 302. The plurality of first ports 310 and the plurality of second ports 320 formed on the chuck stage 302 may be disposed to form a predetermined pattern. For example, as illustrated in FIG. 3A, the plurality of first ports 310 and the plurality of second ports 320 may be formed on the chuck stage 302 to form a lattice pattern when the chuck stage 302 is viewed from above. However, it should be noted that the arrangement structure of the first port 310 and the second port 320 formed on the chuck stage 302 is not limited thereto, and the first port 310 and the second port 320 may be designed and formed in various arrangements to effectively adsorb a wafer.

The first port 310 may include a first flow path 3101 formed through the interior of the chuck stage 302 to selectively communicate with a first through hole 3011 of the backing plate 301. Each of the plurality of first ports 310 may be installed in the first flow path 3101 and may include a shutter 330 that selectively opens and closes the first flow path 3101.

The first flow path 3101 may be formed at least partially in the direction (e.g., Z-axis direction of FIG. 3B) perpendicular to the ground. For example, the first flow path 3101 may be formed to extend from the upper surface of the chuck stage 302 into the interior of the chuck stage 302 in the direction perpendicular to the ground. The first flow path 3101 of each of the plurality of first ports 310 may be connected to a pressure adjuster 360 to receive pressure.

A receiving groove 340 may be formed in at least a portion of the inner circumferential surface of each first flow path 3101. In one or more embodiments, the receiving groove 340 may be recessed from the first flow path 3101 in the direction (e.g., X-axis direction of FIG. 3B) parallel to the ground.

The shutter 330 may be disposed in the receiving groove 340, may move between the receiving groove 340 and the first flow path 3101 along the direction parallel to the ground, and may operate to open and close the first flow path 3101. For example, the state of the shutter 330 may change between a first state and a second state. In the first state, the shutter 330 may be disposed in the receiving groove 340 to open the first flow path 3101, as illustrated in FIG. 3B, and in the second state, the shutter 330 may move from the receiving groove 340 to the first flow path 3101 to close the first flow path 3101, as illustrated in FIG. 3D. The shutter 330 of each of the plurality of first ports 310 may be configured to simultaneously open and close each first flow path 3101.

The shutter 330 may include a compressible sealing member 333, a moving member 331, and a connecting member 332.

The sealing member 333 may be formed of a compressible material, such as rubber, which has waterproof properties. The sealing member 333 may compress or expand depending on the operation of the shutter, thus altering the shape of the sealing member 333. For example, as illustrated in FIG. 3B, when the sealing member 333 is positioned in the receiving groove 340, the sealing member 333 may compress and may be configured to open the first flow path 3101. As illustrated in FIG. 3D, when the sealing member 333 is positioned in the first flow path 3101, the sealing member 333 may expand and may be configured to close the first flow path 3101.

The moving member 331 may operate to move the sealing member 333 between the receiving groove 340 and the first flow path 3101. The moving member 331 may be connected to the sealing member 333 by the connecting member 332 and may operate as a piston in response to receiving power from an actuator 335. For example, the moving member 331 may undergo translational motion in the direction (e.g., X-axis direction) parallel to the ground by the actuator 335.

The plurality of second ports 320 may include a second flow path 3201 formed through the interior of the chuck table 30. The second flow path 3201 may be provided in an open state to maintain communication with a second through hole 3012 of the backing plate 301. A plurality of second flow paths (e.g., 3201) may respectively communicate with a plurality of second through holes (e.g., 3012) formed in the backing plate 301. The second flow path 3201 may remain open, where liquid (e.g., DIW) is sucked or evacuated through the second through hole 3012. In one or more embodiments, the second port 320 may be disposed in the second flow path 3201 and may include a filter 350 for filtering and blocking foreign substances from the liquid flowing into the second flow path 3201. For example, the filter 350 may be formed of a porous material so that only liquid may pass through the filter 350 and may be installed in the second flow path 3201. The filter 350 may be replaceable. The filter 350 may be disposed on the upper portion of the chuck stage 302, for example, on a region of the second flow path 3201 adjacent to the backing plate 301.

Referring to FIG. 3E, In one or more embodiments, each of a plurality of shutters 330 provided in the plurality of first ports 310 may receive power individually by a separate actuator 335, or may operate by receiving power simultaneously from a single actuator 335. For example, the shutter 330 of each of the plurality of first ports 310 may be connected to a single actuator 335 and configured to open and close each of the first flow paths 3101 by moving integrally with the movement of the actuator 335. The plurality of shutters 330 may translate in the direction (e.g., X-axis direction) parallel to each other by a single actuator 335 to open and close the first flow path 3101. According to this structure, the number of actuators 335 disposed on the chuck stage 302 to operate the plurality of shutters 330 may be reduced, thereby simplifying the structure of the chuck stage 302 and improving convenience of maintenance and management.

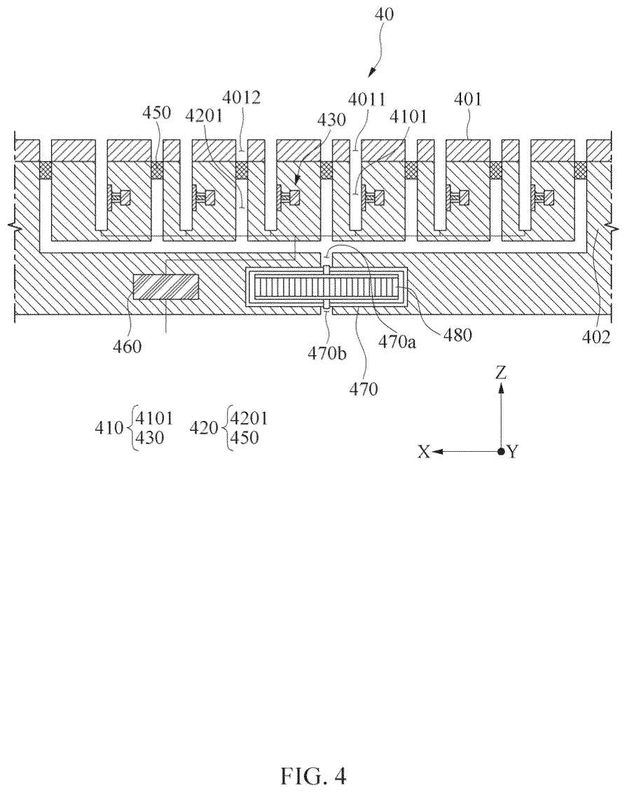

FIG. 4 is a partial cross-sectional view of a chuck table.

Referring to FIG. 4, a chuck table 40 (e.g., the chuck table 20 of FIG. 2A and the chuck table 30 of FIG. 3A) may include a chuck stage 402, a backing plate 401, a plurality of first ports 410, a plurality of second ports 420, a pressure adjuster 460, a receiving chamber 470, and an absorption filter 480.

In one or more embodiments, the backing plate 401 may include a plurality of first through holes 4011 and a plurality of second through holes 4012 formed through a support surface of the backing plate 401. The plurality of first ports 410 may be formed through the chuck stage 402 and include a first flow path 4101 communicating with a corresponding first through hole 4011 and a shutter 430 for selectively opening and closing the first flow path 4101. The plurality of first ports 410 may be connected to the pressure adjuster 460 and may provide negative pressure to the first through hole 4011 through the first flow path 4101.

In one or more embodiments, the plurality of second ports 420 may be formed through the chuck stage 402 and may include a second flow path 4201 communicating with a corresponding second through hole 4012. The second port 420 may be disposed in the second flow path 4201 and may include a filter 450 for filtering and blocking foreign substances from the liquid flowing through the second through hole 4012. The respective second flow paths 4201 of the plurality of second ports 420 may be integrated in the chuck stage 402. For example, the respective second flow paths 4201 of the plurality of second ports 420 may be connected to communicate with the receiving chamber 470 disposed in the chuck stage 402.

In one or more embodiments, the receiving chamber 470 may be disposed in the chuck stage 402. The receiving chamber 470 may accommodate the liquid sucked through the plurality of second ports 420. The receiving chamber 470 may communicate with the plurality of second flow paths 4201 and include an inlet 470a through which a fluid flows into the plurality of second flow paths 4201 and an outlet 470b communicating with the exterior of the chuck table 40.

In one or more embodiments, the absorption filter 480 for absorbing the introduced liquid may be disposed in the receiving chamber 470. The absorption filter 480 may absorb and remove the fluid flowing into the receiving chamber 470 through the plurality of second flow paths 4201. The absorption filter 480 may be installed in the receiving chamber 470. The absorption filter 480 may be replaceable. In one or more embodiments, a residual liquid that is not removed by the absorption filter 480 among the liquid introduced into the receiving chamber 470 may be discharged to the outside of the chuck table 40 through the outlet 470b.

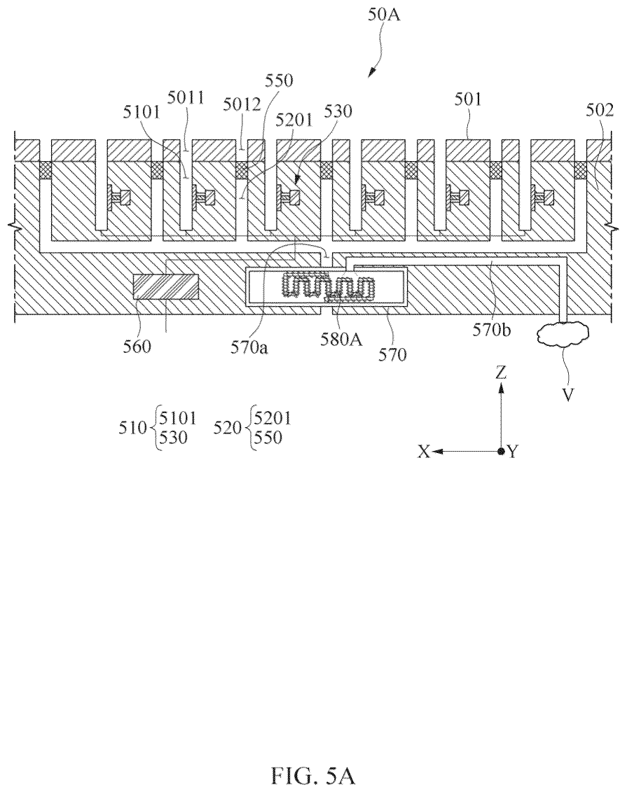

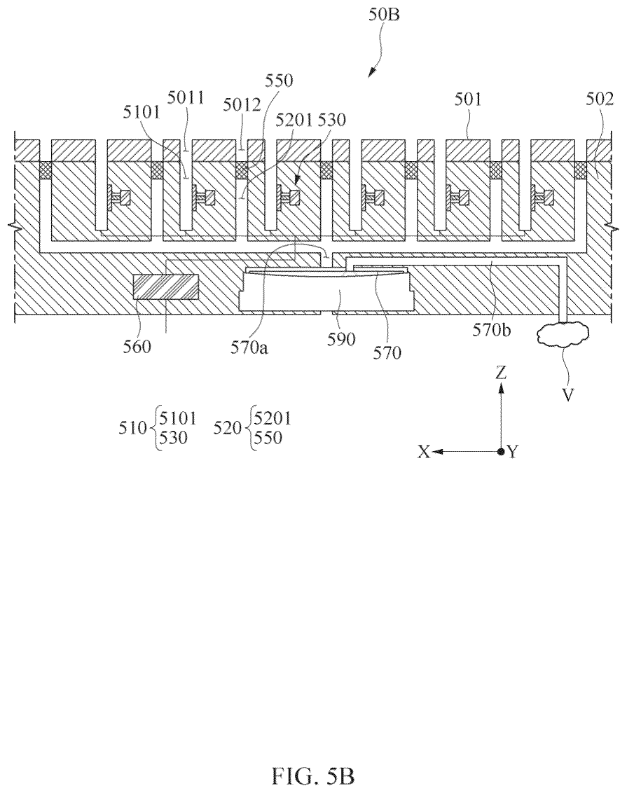

FIG. 5A is a partial cross-sectional view of a chuck table. FIG. 5B is a partial cross-sectional view of the chuck table.

Referring to FIG. 5A, a chuck table 50A may include a chuck stage 502, a backing plate 501, a plurality of first ports 510, a plurality of second ports 520, a pressure adjuster 560, a receiving chamber 570, and a heating member 580A.

In one or more embodiments, the backing plate 501 may include a plurality of first through holes 5011 and a plurality of second through holes 5012 formed through a support surface of the backing plate 501. The plurality of first ports 510 may be formed through the chuck stage 502 and include a first flow path 5101 communicating with a corresponding first through hole 5011 and a shutter 530 for selectively opening and closing the first flow path 5101. The plurality of first ports 510 may be connected to the pressure adjuster 560 and may provide negative pressure to the first through hole 5011 through the first flow path 5101.

In one or more embodiments, the plurality of second ports 520 may be formed through the chuck stage 502 and may include a second flow path 5102 communicating with a corresponding second through hole 5012. The second port 520 may be disposed in the second flow path 5102 and may include a filter 550 for filtering and blocking foreign substances from the liquid flowing through the second through hole 5012. The respective second flow paths 5102 of the plurality of second ports 520 may be integrated in the chuck stage 502. For example, the respective second flow paths 5102 of the plurality of second ports 520 may be connected to communicate with the receiving chamber 570 disposed in the chuck stage 502.

In one or more embodiments, the receiving chamber 570 may be disposed in the chuck stage 502. The receiving chamber 570 may accommodate a liquid sucked through the plurality of second ports 520. The receiving chamber 570 may communicate with the plurality of second flow paths 5102 and include an inlet 570a through which the fluid flows into the plurality of second flow paths 5102 and an outlet 570b communicating with the exterior of the chuck table 50.

In one or more embodiments, a heating member 580A for evaporating the liquid introduced into the receiving chamber 570 may be disposed in the receiving chamber 570. The heating member 580A may be provided as a pipe through which the liquid introduced into the receiving chamber 570 may flow and may be configured to heat and evaporate the liquid flowing therein. For example, the heating member 580A may be provided as an evaporation pipe coated with a heating wire on the outer surface of the heating member 580A. In one or more examples, the heating member 580A may be provided as a thermoelectric element installed in the receiving chamber 570. For example, various known heating methods of evaporating the liquid introduced into the receiving chamber 570 may be used as the heating member 580A. The gas V evaporated by the heating member 580A in the receiving chamber 570 may be discharged to the outside of the chuck table 50 through the outlet 570b.

In one or more embodiments, as illustrated in FIG. 5B, a chuck table 50B may be mounted on the outer surface of the receiving chamber 570 and may include a heating jacket 590 for heating the receiving chamber 570. In one or more embodiments, the heating jacket 590 may be configured to evaporate the liquid, that is, moisture, introduced into the receiving chamber 570 to change the liquid into the gas V and remove the gas V by covering the outer surface of the receiving chamber 570 and heating the interior of the receiving chamber 570.

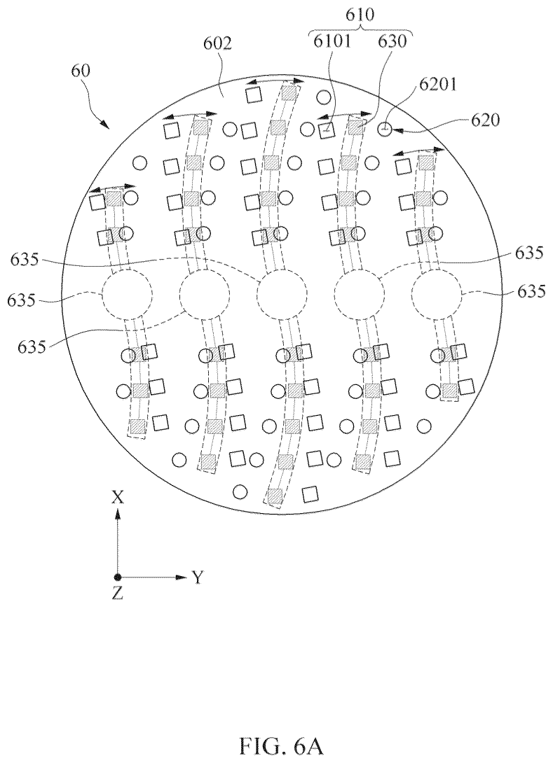

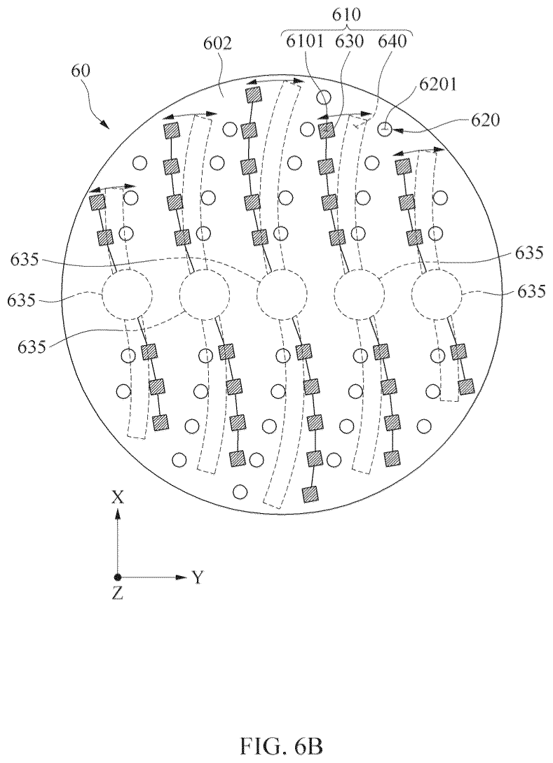

FIG. 6A is a plan view of a chuck table and illustrates a state in which a first port is open. FIG. 6B is a plan view of the chuck table and illustrates a state in which the first port is closed.

Referring to FIGS. 6A and 6B, a chuck table 60 may include a plurality of first ports 610 (or a vacuum port) that provides vacuum pressure for adsorbing a wafer and a plurality of second ports 620 (or a suction port) for sucking the liquid remaining on the upper surface of the chuck table 60. Each of the plurality of first ports 610 may include a plurality of first flow paths 6101 formed in the chuck stage 602 and a shutter 630 that operates to selectively open and close a first flow path 6101. The plurality of second ports 620 may include a plurality of second flow paths 6201 formed in the chuck stage 602 and remains open.

In one or more embodiments, at least some of the plurality of first ports 610 formed on the chuck table 60 may be configured to be operated by a single actuator 635. For example, the plurality of first ports 610 may be grouped into a plurality of first port groups, and first ports 610 included in the same first port group may be configured to have shutters 630 operated simultaneously by a single actuator 635.

In one or more embodiments, the first ports 610 included in the same first port group may be arranged in a curve shape around a single actuator 635, as illustrated in FIG. 6A. As illustrated in FIG. 6A, in a state in which the upper portion of the chuck stage 602 is viewed, the respective shutters 630 of the first ports 610 of the same first port group may move between a first flow path 6101 and a receiving groove 640 by being rotated as a whole around a center point by a single actuator 635. For example, FIG. 6A illustrates that five first port groups are formed. The shutters 630 of first ports 610 included in the same first port group may operate to open and close each corresponding first flow path 6101 by being rotated in the radial direction around a center point by a single actuator 635. In one or more examples, each actuator 635 may be operated independently, where one or more of the actuators are operated to close a respective first port group while one or more other first port groups remain open.

In one or more embodiments, a second port 620 may be formed on a region of the chuck stage 602 that does not overlap a first port 610.

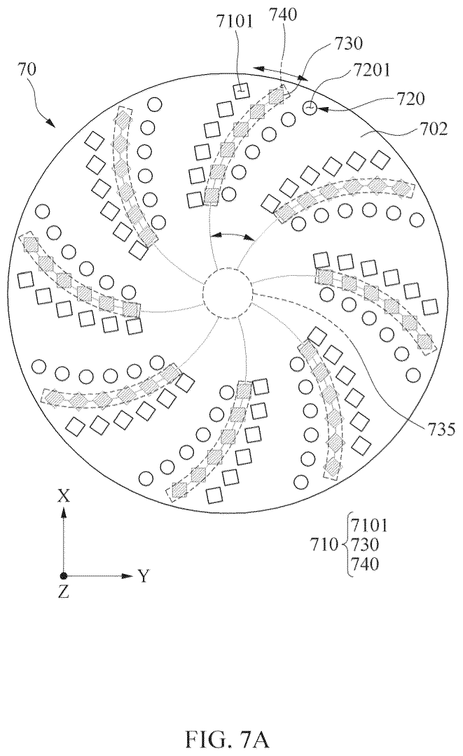

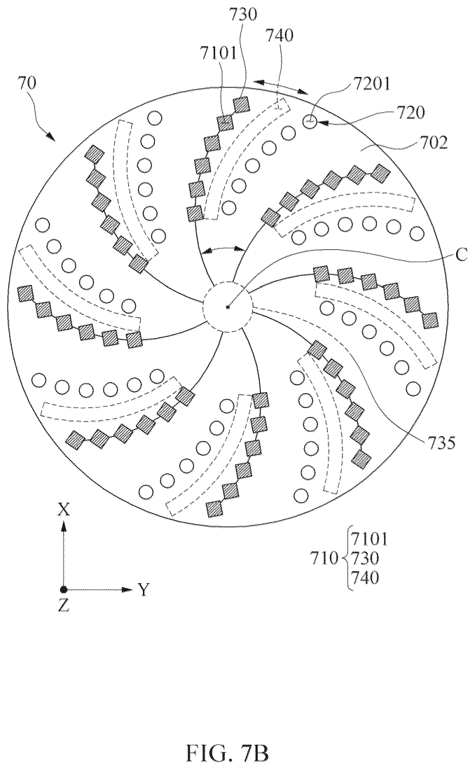

FIG. 7A is a plan view of a chuck table and illustrates a state in which each first port is open. FIG. 7B is a plan view of the chuck table and illustrates a state in which each first port is closed.

Referring to FIGS. 7A and 7B, a chuck table 70 (e.g., the chuck table 10 of FIG. 1) may include a plurality of first ports 710 (or vacuum ports) that provides vacuum pressure for adsorbing a wafer and a plurality of second ports 720 (or suction ports) in which the liquid remaining on the upper surface of the chuck table 70 is sucked through the second ports 720. Each of the plurality of first ports 710 may include a plurality of first flow paths 7101 formed in the chuck stage 702 and a shutter 730 that operates to selectively open and close the first flow paths 7101. The plurality of second ports 720 may include a plurality of second flow paths 7201 formed in the chuck stage 702 that remain open.

The plurality of first ports 710 formed on the chuck table 70 may be configured to be operated by a single actuator 735. As illustrated in FIG. 7A, the plurality of first ports 710 may be arranged in a spiral shape around the center C of the chuck stage 702. For example, the shutter 730 of each of the plurality of first ports 710 may be arranged in a radial direction around the center C of the chuck stage 702. The shutter 730 of each of the plurality of first ports 710 may be rotated around the center C of the chuck stage 702 by a single actuator 735, and may move between a corresponding first flow path 7101 and a corresponding receiving groove 740. For example, the respective shutters 730 of the plurality of first ports 710 may operate to open and close corresponding first flow paths 7101 while simultaneously being rotated by the rotation movement of the actuator 735.

In one or more embodiments, a second port 720 may be formed on a region of the chuck stage 702 that does not overlap a first port 710.

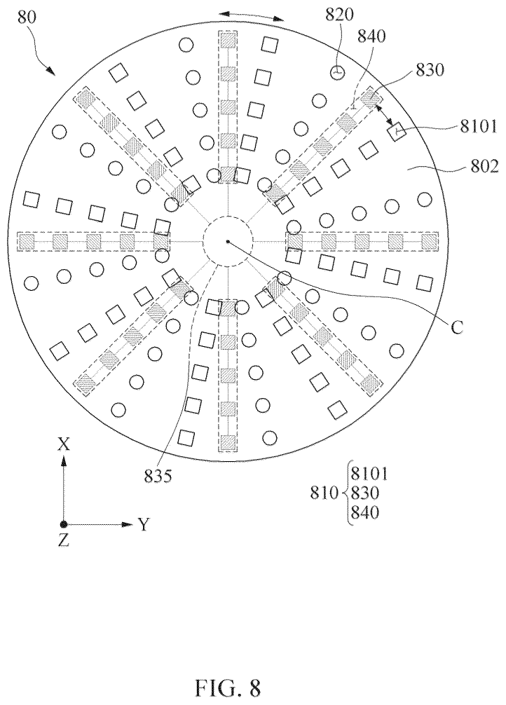

FIG. 8 is a plan view of a chuck table.

Referring to FIG. 8, a chuck table 80 (e.g., the chuck table 10 of FIG. 1) may include a plurality of first ports 810 (or vacuum ports) that provides vacuum pressure for adsorbing a wafer and a plurality of second ports 820 (or suction ports) for sucking the liquid remaining on the upper surface of the chuck table 80. Each of the plurality of first ports 810 may include a plurality of first flow paths 8101 formed in a chuck stage 802 and a shutter 830 that operates to selectively open and close the first flow paths 8101. The plurality of second ports 820 may include a plurality of second flow paths 8201 formed in the chuck stage 802 and remains open.

The plurality of first ports 810 formed on the chuck table 80 may be configured to be operated by a single actuator 835. As illustrated in FIG. 8, the plurality of first ports 810 may be arranged to be linearly spaced apart from each other in the radial direction with respect to the center C of the chuck stage 802. The shutter 830 of each of the plurality of first ports 810 may be rotated around the center C of the chuck stage 802 by a single actuator 835 and may move between a corresponding first flow path 8101 and a corresponding receiving groove 840. For example, the respective shutters 830 of the plurality of first ports 810 may operate to open and close corresponding first flow paths 8101 while simultaneously being rotated by the rotation movement of the actuator 835.

In one or more embodiments, a second port 820 may be formed on a region of the chuck stage 802 that does not overlap a first port 810.

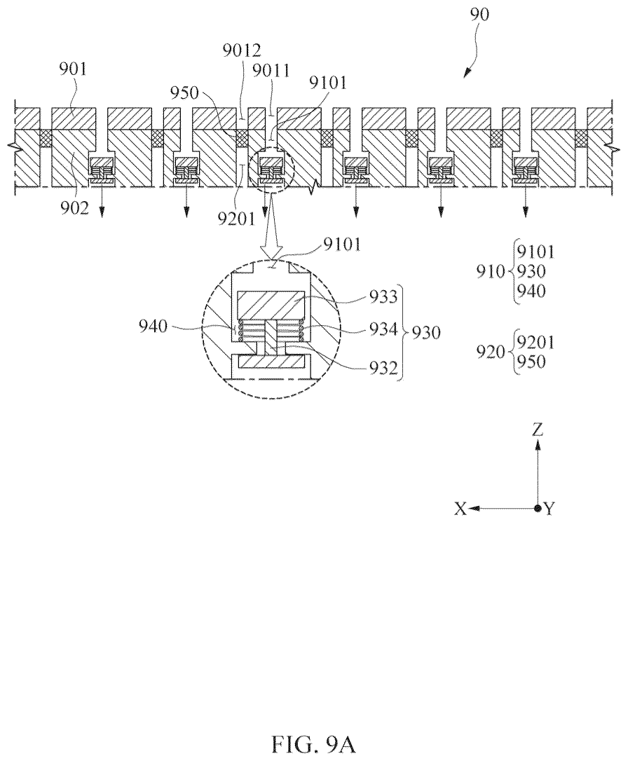

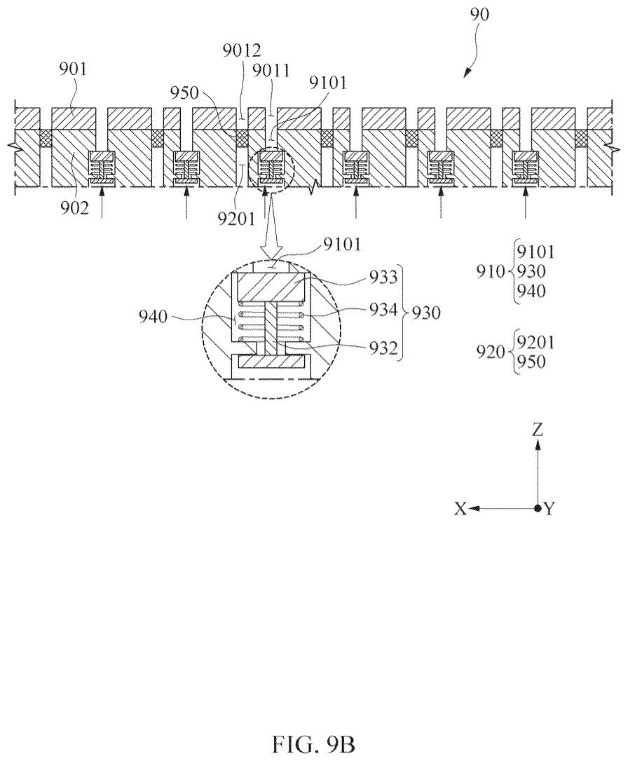

FIG. 9A is a partial cross-sectional view of a chuck table and illustrates a state in which a first port is open. FIG. 9B is a partial cross-sectional view of the chuck table and illustrates a state in which the first port is closed.

Referring to FIGS. 9A and 9B, a chuck table 90 (e.g., the chuck table 10 of FIG. 1) may include a chuck stage 902, a backing plate 901 forming a support surface, a plurality of first ports 910 formed in the chuck stage 902, and a plurality of second ports 920 formed in the chuck stage 902.

A first port 910 may be open and closed to selectively communicate with a first through hole of the backing plate 901. In one or more embodiments, a second port 920 may be provided in an open state to maintain communication with a second through hole of the backing plate 901.

Each of the plurality of first ports 910 may be formed through the interior of the chuck stage 902 and may include a first flow path 9101 through which air flows and a shutter 930 installed in the first flow path 9101 to selectively open and close the first flow path 9101.

The first flow path 9101 may be formed at least partially in the direction perpendicular to the ground (e.g., Z-axis direction of FIG. 3C). For example, the first flow path 9101 may be formed to extend from the upper surface of the chuck stage 902 into the interior of the chuck stage 902 in the direction perpendicular to the ground. The first flow path 9101 of each of the plurality of first ports 910 may be connected to a pressure adjuster (e.g., the pressure adjuster 560 of FIG. 5A) and may receive pressure.

A first port 910 may include a receiving portion 940 formed on the first flow path 9101. In one or more embodiments, the receiving portion 940 may be formed in the direction perpendicular to the ground, and the upper and lower ends of the receiving portion 940 may be connected to the first flow path 9101. The receiving portion 940 may be formed to have a greater cross-sectional area than the first flow path 9101.

The shutter 930 may be installed to be partially movable in the receiving portion 940. For example, the shutter 930 may move along the direction perpendicular to the ground in the receiving portion 940 and operate to open and close the first flow path 9101. For example, the state of the shutter 930 may change between a first state and a second state. In the first state, the shutter 930 may move to the lower portion of the receiving portion 940 and open the first flow path 9101, as illustrated in FIG. 9A, and in the second state, the shutter 930 may move to the upper portion of the receiving portion 940 and close the first flow path 9101, as illustrated in FIG. 9B. The shutter 930 of each of the plurality of first ports 910 may be configured to simultaneously open and close each corresponding first flow path 9101. In one or more embodiments, the shutter 930 may include a sealing member 933, an elastic member 934, and a moving member 932.

The sealing member 933 may be formed of a compressible material, such as rubber, which has waterproof properties. The sealing member 933 may be configured to open the first flow path 9101 when positioned at the lower portion of the receiving portion 940, as illustrated in FIG. 9A, and close the first flow path 9101 by coming into close contact with the upper portion of the receiving portion 940 when positioned at the upper end of the receiving portion 940, as illustrated in FIG. 9B. Based on the state in which the chuck table 90 is viewed from above, the sealing member 933 may have a greater cross-sectional area than the first flow path 9101 and may be disposed in the receiving portion 940 to overlap the first flow path 9101. Accordingly, when the sealing member 933 is positioned on the upper portion of the receiving portion 940, the sealing member 933 may completely cover and close the first flow path 9101 positioned on the upper portion of the receiving portion 940.

The elastic member 934 may be connected to the sealing member 933 and may press the sealing member 933 upward into the receiving portion 940. When no separate external force (e.g., negative pressure) acts on the sealing member 933, the elastic member 934 may exert upward elastic force on the sealing member 933 to allow the sealing member 933 to be in contact with the upper end of the receiving portion 940. For example, when negative pressure is not applied to the first port 910, the elastic member 934 may press the sealing member 933 upward into the receiving portion 940 such that the sealing member 933 closes the first flow path 9101.

In one or more embodiments, when negative pressure is applied to the first port 910, such as when negative pressure is directed downward toward the receiving portion 940, the sealing member 933 may operate to open the first flow path 9101 while moving downward into the receiving portion 940. For example, the moving member 932 may be connected to the lower portion of the sealing member 933, and the moving member 932 may be configured to exert external force to pull the sealing member 933 downward into the receiving portion 940 in response to negative pressure acting on the first port 910. When the sealing member 933 moves downward into the receiving portion 940 to open the first flow path 9101, the elastic member 934 may be compressed by the sealing member 933. When the negative pressure acting on the first port 910 is released, the elastic member 934 may move the sealing member 933 upward into the receiving portion 940 by restoring force, thereby closing the first flow path 9101.

Each shutter 930 provided in the plurality of first ports 910 operates to open and close the first flow path 9101 by the negative pressure acting on the first port 910. Therefore, when the plurality of first ports 910 receives negative pressure simultaneously from a pressure adjuster (e.g., the pressure adjuster 460 of FIG. 4), the opening and closing operations of the plurality of first ports 910 may be performed simultaneously.

An example in which the sealing member 933 opens and closes the first flow path 9101 while being moved in the receiving portion 940 by negative pressure and the elastic member 934 is described with reference to FIGS. 9A and 9B. However, the sealing member 933 may also be configured to open and close the first flow path 9101 while being moved in the direction perpendicular to the ground in the receiving portion 940 by a separately provided actuator. According to this structure, the number of actuators disposed on the chuck stage 902 to operate the plurality of shutters 930 may be reduced, thereby simplifying the structure of the chuck stage 902 and improving convenience of maintenance and management.

The plurality of second ports 920 may include a second flow path 9201 formed through the interior of the chuck table 90. The plurality of second flow paths 9201 may communicate with a plurality of second through holes formed in the backing plate 901, respectively. A second flow path 9201 may remain open to suck a liquid (e.g., DIW) introduced through a second through hole. A second port 920 may be disposed in the second flow path 9201 and may include a filter 950 for filtering and blocking foreign substances from the liquid flowing into the second flow path 9201. For example, the filter 950 may be formed of a porous material so that only liquid may pass through the filter 950 and may be installed in the second flow path 9201. The filter 950 may be replaceable. In one or more embodiments, the filter 950 may be disposed on the upper portion of the chuck stage 902, for example, on a region of the second flow path 9201 adjacent to the backing plate 901.

Hereinafter, a wafer cleaning method is described. In describing the wafer cleaning method, it may be understood that terms that are redundant with those previously described refer to similar or identical elements unless otherwise described.

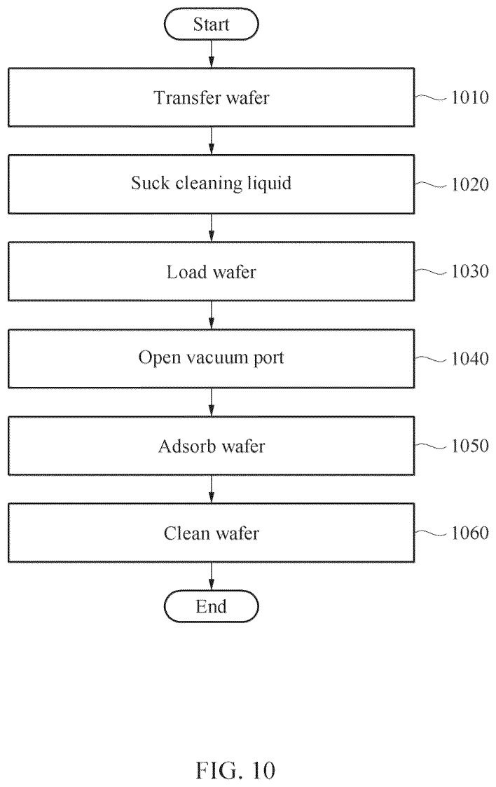

FIG. 10 is a flowchart of a wafer cleaning method.

Referring to FIG. 10, the wafer cleaning method may be performed by a wafer cleaning device (e.g., the wafer cleaning device 1 of FIG. 1). At least one of the operations of the wafer cleaning method may be omitted. It should be noted that at least two or more operations of the wafer cleaning method are not necessarily performed sequentially unless specifically limited by order. At least two or more operations of the wafer cleaning method may be performed simultaneously or repeated.

The wafer cleaning method may include operation 1010 in which a wafer is moved to a position adjacent to a chuck table (e.g., the chuck table 10 of FIG. 1), operation 1020 of sucking a cleaning liquid remaining on the surface of the chuck table, operation 1030 of loading the wafer onto the chuck table, operation 1040 of opening a vacuum port of the chuck table, operation 1060 of adsorbing the wafer loaded on the chuck table, and operation 1050 of cleaning the wafer.

Operation 1010 may be performed by a wafer transfer. The wafer transfer may grip a wafer to be cleaned and may transfer the gripped wafer to a position adjacent to the chuck table, for example, to a position of the chuck table on which the wafer may be loaded.

Operation 1020 may be performed before the wafer is loaded onto the chuck table. Operation 1020 may be performed in which liquid is sucked or evacuated through a suction port (e.g., the second port 220 in FIG. 2) formed on the chuck table. A cleaning liquid sprayed during the previous cleaning process may remain on a support surface of the chuck table. The cleaning liquid may be, for example, DIW to be sprayed onto the surface of the wafer. In operation 1020, at least some of the cleaning liquid remaining on the support surface of the chuck table may be sucked through the suction port, thereby reducing the thickness of a water film formed by the cleaning liquid within a set range. In this case, the phenomenon of the wafer seated on the chuck table slipping from the support surface may be advantageously minimized or reduced.

In operation 1030, the wafer may be loaded onto the support surface of the chuck table. In one or more embodiments, operation 1030 may be performed when the cleaning liquid remaining on the support surface of the chuck table is reduced to a set thickness or less. For example, operation 1030 may be performed after operation 1020 is performed for a set period of time or longer. Alternatively, operation 1030 may be performed according to information provided by a separate sensor for detecting the thickness of the cleaning liquid.

When the thickness of the water film formed on the support surface of the chuck table is reduced to a sufficient range, operation 1030 may be performed so that the wafer to be cleaned may be loaded on the support surface.

Operation 1040 may be performed after operation 1030 is performed. Operation 1040 may be performed simultaneously with operation 1030. In operation 1040, a vacuum port (e.g., the first port 210 of FIG. 2) formed on the chuck table may be open. The vacuum port may be closed when the wafer is not seated on the chuck table, for example, during operations 1010, 1020, and 1030, to prevent communication with the support surface. For example, the opening and closing operation of the vacuum port may be performed by a shutter (e.g., the shutter 330 of FIG. 3A).

Operation 1050 may be performed after operation 1040 is completed. In operation 1050, negative pressure may be applied to the vacuum port. The negative pressure applied to the vacuum port may adsorb the wafer seated on the support surface of the chuck table. For example, the position of the wafer seated on the chuck table may be stably maintained by the vacuum port.

In operation 1060, cleaning of the wafer adsorbed to the chuck table may be performed. For example, a cleaning liquid may be sprayed onto the surface of the wafer, and a cleaning module may be in contact with a surface (e.g., a polishing surface) of the wafer and operate to remove foreign substances or polishing debris from the surface of the wafer. In operation 1060, the wafer may be rotated by the chuck table. Since the wafer is sufficiently adsorbed to the chuck table through the vacuum port, the position of the wafer relative to the chuck table may be stably maintained during the wafer cleaning process.

Although the examples have been described with reference to the limited drawings, one of ordinary skill in the art may apply various technical modifications and variations based thereon. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents of the claims are within the scope of the following claims.

What is claimed is:

1. A chuck table comprising:
a chuck stage configured to have a wafer seated thereon;
a plurality of first ports on the chuck stage and configured to adsorb the wafer to the chuck stage;
a plurality of second ports on the chuck stage and configured to have a liquid from the chuck stage sucked therethrough; and
a pressure adjuster connected to the plurality of first ports and configured to provide a vacuum pressure,
wherein each of the plurality of first ports is configured to be selectively opened and closed to communicate with an exterior of the chuck stage, and
wherein the plurality of second ports are open to communicate with the exterior of the chuck stage.

2. The chuck table of claim 1, wherein each of the plurality of first ports comprises:
a first flow path in the chuck stage and through which air flows; and
a shutter in the first flow path and configured to selectively open and close the first flow path.

3. The chuck table of claim 2, wherein the first flow path extends along a first direction,
wherein the shutter is disposed in a receiving groove configured to communicate with an inner circumferential surface of the first flow path, and
wherein the shutter is configured to open and close the first flow path while moving between the receiving groove and the first flow path along a second direction perpendicular to the first direction.

4. The chuck table of claim 3, wherein the shutter comprises:
a compressible sealing member; and
a moving member connected to the compressible sealing member and configured to move the compressible sealing member between the receiving groove and the first flow path by receiving power by an actuator, and
wherein the compressible sealing member is in a state of compression when positioned in the receiving groove, and in a state of expansion to close the first flow path when positioned in the first flow path.

5. The chuck table of claim 2, wherein the plurality of first ports are grouped into a plurality of first port groups, and each of the plurality of first ports included in a same first port group are configured to have a respective shutter operated simultaneously by a single actuator.

6. The chuck table of claim 5, wherein each of the shutter of the first ports included in the same first port group is configured to open and close by rotation around a center point by a single actuator.

7. The chuck table of claim 5, wherein each of the shutter of the plurality of first ports included in the same first port group is configured to open and close by translation in a direction parallel to each other by a single actuator.

8. The chuck table of claim 2, wherein shutters of the plurality of first ports are disposed in a form of a linear lattice, and
the shutters of the plurality of first ports is configured to be simultaneously opened and simultaneously closed by a single actuator.

9. The chuck table of claim 2, further comprising:
an actuator is in a center of the chuck stage,
wherein a shutter of each of the plurality of first ports is disposed in a radial direction around the center of the chuck stage and configured to be opened and closed by rotation around the center of the chuck stage by the actuator.

10. The chuck table of claim 1, further comprising:
a backing plate disposed on the chuck stage and comprising a support surface on which the wafer is seated,
wherein the backing plate comprises:
a plurality of first through holes passing through the support surface and communicating respectively with the plurality of first ports; and
a plurality of second through holes passing through the support surface and communicating respectively with the plurality of second ports.

11. The chuck table of claim 1, wherein each of the plurality of second ports comprises:
a second flow path in the chuck stage; and
a filter in the second flow path and configured to block a foreign substance.

12. The chuck table of claim 11, further comprising:
a receiving chamber in the chuck stage, the receiving chamber comprising an inlet communicating with the second flow path of each of the plurality of second ports and an outlet communicating with an exterior of the chuck stage,
wherein an absorption filter configured to absorb the liquid from the chuck stage introduced into the receiving chamber through the plurality of second ports is in the receiving chamber.

13. The chuck table of claim 1, further comprising:
a receiving chamber in the chuck stage, the receiving chamber comprising an inlet communicating with the plurality of second flow paths and an outlet communicating with an exterior of the chuck stage,
wherein a heating member configured to evaporate the liquid from the chuck stage introduced into the receiving chamber through the plurality of second ports is in the receiving chamber, and
wherein the outlet is configured to discharge a gas evaporated from the receiving chamber to an outside of the chuck stage.

14. The chuck table of claim 1, wherein the plurality of first ports is configured to be open in a state in which the wafer is seated on the chuck stage, and
wherein the pressure adjuster is configured to provide the vacuum pressure in a state in which the plurality of first ports is open.

15. The chuck table of claim 2, wherein each of the plurality of first ports includes a receiving portion connected to the first flow path in the first direction, the receiving portion having a greater cross sectional area than the first flow path,
wherein the shutter is configured to be partially movable in the receiving portion,
wherein the shutter comprises:
a sealing member; and
an elastic member connected sealing member and configured to press sealing member upward into the receiving portion, and
wherein the sealing member is configured to close the first flow path when positioned at an upper portion of the receiving portion, and to open the first flow path while moving downward into the receiving portion when negative pressure acts on the first port.

16. A wafer cleaning device comprising:
a chuck table configured to support a wafer;
a fluid supplier configured to supply a cleaning liquid to the wafer on the chuck table; and
a cleaning module configured to clean the wafer on the chuck table,
wherein the chuck table comprises:
a chuck stage;
a backing plate on the chuck stage, the backing plate comprising a support surface configured to have the wafer seated thereon, the backing plate comprising a plurality of first through holes and a plurality of second through holes passing through the support surface;
a plurality of first ports on the chuck stage and configured to communicate with the plurality of first through holes and to adsorb the wafer to the support surface;
a plurality of second ports on the chuck stage and configured to communicate with the plurality of second through holes and configured to have the cleaning liquid from the support surface sucked therethrough; and
a pressure adjuster connected to the plurality of first ports and configured to provide a vacuum pressure,
wherein each of the plurality of first ports is configured to be selectively opened and closed to communicate with the plurality of first through holes, and
wherein the plurality of second ports are open to communicate with the plurality of second through holes.

17. The wafer cleaning device of claim 16, wherein each of the plurality of first ports comprises:
a first flow path in the chuck stage;
a receiving groove in an inner circumferential surface of the first flow path; and
a shutter in the receiving groove and configured to receive power to open and close the first flow path.

18. The wafer cleaning device of claim 17, wherein the shutter of at least two or more of the plurality of first ports of the plurality of first ports is configured to simultaneously open and close by an actuator.

19. The wafer cleaning device of claim 17, wherein each of the plurality of first ports is configured to open when the wafer is seated on the support surface and to close when the wafer is not seated on the support surface.

20. A wafer cleaning method comprising:
transferring a wafer to a position adjacent to a chuck table;
sucking a cleaning liquid remaining on a support surface of the chuck table through a suction port on the chuck table;
loading the wafer onto the support surface of the chuck table;
opening a vacuum port on the chuck table;
adsorbing the wafer loaded onto the chuck table by providing negative pressure to the vacuum port; and
cleaning the wafer adsorbed to the chuck table.
